(19) United States
(12) Patent Application Publication
(10) Pub. No.: US 2026/0075846 A1
(43) Pub. Date: Mar. 12, 2026

(54) MEMORY DEVICE

(71) Applicant: SK hynix Inc., Gyeonggi-do (KR)

(72) Inventor: Heon Yong CHANG, Gyeonggi-do (KR)

(21) Appl. No.: 19/014,256

(22) Filed: Jan. 9, 2025

(30) Foreign Application Priority Data
Sep. 10, 2024 (KR) 10-2024-0122800

(51) Int. Cl. H10B 80/00; H01L 23/00; H01L 25/00; H01L 25/065; H01L 25/18

(52) U.S. Cl. CPC H10B 80/00; H10W 90/00; H10W 80/312; H10W 80/327; H10W 90/792

(57) ABSTRACT

A memory device including a first semiconductor structure including a bit line extending in a first direction, a second semiconductor structure disposed below the first semiconductor structure, a first bonding structure disposed between the first semiconductor structure and the second semiconductor structure, and including a first bonding contact, and a second bonding structure disposed between the first bonding structure and the second semiconductor structure, and including a second bonding contact, wherein the first bonding contact may penetrate the bit line in a direction perpendicular to the first direction.

### CROSS-REFERENCE TO RELATED APPLICATION

The present application claims priority under 35 U.S.C. 119(a) to Korean patent application number 10-2024-0122800 filed on Sep. 10, 2024, which is incorporated herein by reference in its entirety.

### TECHNICAL FIELD

The embodiments of the present disclosure relate generally to semiconductor technology, and, more particularly, to a memory device.

### BACKGROUND

A memory device is an important component in an electronics industry owing to their characteristics such as miniaturization, multi-functionality, and/or low manufacturing cost. As the electronics industry develops, memory devices are gradually becoming more highly integrated. In order to achieve high integration of the memory device, it is required to reduce a line width of a wiring included in the memory device, which increases the difficulty of the process of forming the memory device.

### SUMMARY

Various embodiments of the present disclosure provide a memory device capable of preventing the deterioration of device characteristics due to process defects.

Various embodiments of the present disclosure provide a memory device including a first semiconductor structure including a bit line extending in a first direction, a second semiconductor structure disposed below the first semiconductor structure, a first bonding structure disposed between the first semiconductor structure and the second semiconductor structure, and including a first bonding insulating layer, a first bonding pad disposed within the first bonding insulating layer, and a first bonding contact connected to the first bonding pad, and a second bonding structure disposed between the first bonding structure and the second semiconductor structure, and including a second bonding insulating layer, a second bonding pad disposed within the second bonding insulating layer and having an upper surface in contact with a lower surface of the first bonding pad, and a second bonding contact connected to the second bonding pad, wherein the first bonding contact penetrates the bit line in a direction perpendicular to the first direction. An upper surface of an element as this term is used here may refer to the top surface of the element. Also, a lower surface of an element as this term is used here may refer to the bottom surface of the element.

Various embodiments of the present disclosure may provide a memory device including a first semiconductor structure including a bit line extending in a first direction, a second semiconductor structure disposed below the first semiconductor structure, a first bonding structure disposed between the first semiconductor structure and the second semiconductor structure, and including a first bonding insulating layer, a first bonding pad disposed within the first bonding insulating layer, and a first bonding contact connected to the first bonding pad, and a second bonding structure disposed between the first bonding structure and the second semiconductor structure, and including a second bonding insulating layer, a second bonding pad disposed within the second bonding insulating layer and having an upper surface in contact with a lower surface of the first bonding pad, and a second bonding contact connected to the second bonding pad, wherein the bit line includes a first portion and a second portion spaced apart from the first portion in the first direction, and the first bonding contact is located between the first portion and the second portion of the bit line.

According to an embodiment of the present disclosure, it is possible to prevent the deterioration of device characteristics of a memory device due to process defects.

### BRIEF DESCRIPTION OF THE DRAWINGS

FIG. 1 is a simplified block diagram of a memory device according to an embodiment of the present disclosure.

FIG. 2 illustrates an equivalent circuit diagram of a memory cell array illustrated in FIG. 1.

FIG. 3 illustrates a cross-sectional structure of a memory device according to an embodiment of the present disclosure.

FIG. 4A to FIG. 4C and FIG. 5A to FIG. 5C illustrate examples of a three-dimensional structure and a planar structure of the memory device illustrated in FIG. 3.

FIG. 6 illustrates another example of a cross-sectional structure of a memory device according to an embodiment of the present disclosure.

FIG. 7A to FIG. 7C and FIG. 8A to FIG. 8C illustrate examples of a three-dimensional structure and a planar structure of the memory device illustrated in FIG. 6.

FIG. 9 to FIG. 16 illustrate examples of a method for manufacturing a memory device according to an embodiment of the present disclosure.

FIG. 17 and FIG. 18 illustrate other examples of a method for manufacturing a memory device according to an embodiment of the present disclosure.

### DETAILED DESCRIPTION

Hereinafter, various embodiments of the present disclosure will be described in detail with reference to accompanying drawings.

In the attached drawings, two directions parallel to an upper surface of a substrate are defined as a first direction FD and a second direction SD, respectively, and a direction protruding vertically from the upper surface of the substrate is defined as a third direction VD. The first direction FD and the second direction SD may be perpendicular or substantially perpendicular to each other. The third direction VD may be a direction perpendicular to the first direction FD and the second direction SD. In the following specification, ‘vertical’ or ‘vertical direction’ will be used to have substantially the same meaning as the third direction VD. A direction indicated by an arrow in the drawings and its opposite direction may indicate the same direction.

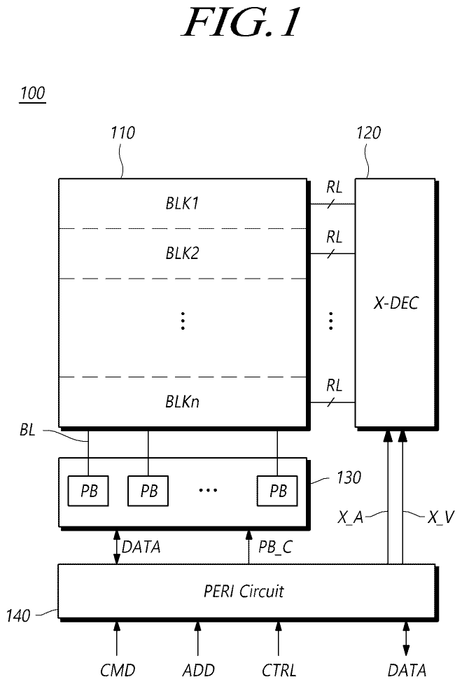

FIG. 1 is a block diagram of a memory device according to an embodiment of the present disclosure.

Referring to FIG. 1, a memory device 100 according to an embodiment of the present disclosure may include a memory cell array 110, a row decoder (X-DEC) 120, a page buffer circuit 130), and a peripheral circuit (PERI Circuit) 140.

The memory cell array 110 may include a plurality of memory blocks BLK1-BLKn where n is a natural number greater than or equal to 2. The memory blocks BLK1-BLKn may each include a plurality of cell strings. The cell strings may include at least one drain select transistor, a plurality of memory cells, and at least one source select transistor which are connected in series. The memory cell may be a volatile memory cell or a non-volatile memory cell. Hereinafter, the memory device 100 is described as a vertical NAND flash device, but it should be understood that the technical concept of the present disclosure is not limited thereto.

The row decoder 120 may be connected to the memory cell array 110 through a plurality of row lines RL. The row lines RL may include at least one drain select line, a plurality of word lines, and at least one source select line.

The row decoder 120 may select one of the memory blocks BLK1-BLKn included in the memory cell array 110 in response to the row address X_A received from the peripheral circuit 140. The row decoder 120 may transmit the operating voltage X_V received from the peripheral circuit 140 to the row lines RL connected to the selected memory block among the memory blocks BLK1-BLKn included in the memory cell array 110.

The memory cell array 110 may be connected to the page buffer circuit 130 through a plurality of bit lines BL. The page buffer circuit 130 may include a plurality of page buffers PB connected to the memory cell array 110 via the bit lines BL. The page buffer circuit 130 may receive a page buffer control signal PB_C from the peripheral circuit 140. The page buffer circuit 130 may also transmit and receive data signal DATA to and from the peripheral circuit 140. The page buffer circuit 130 may control the bit line BL arranged in the memory cell array 110 in response to the page buffer control signal PB_C. For example, the page buffer circuit 130 may detect data stored in a memory cell of the memory cell array 110 by detecting a signal of a bit line BL of the memory cell array 110 in response to the page buffer control signal PB_C, and may transmit a data signal DATA to the peripheral circuit 140 according to the detected data. The page buffer circuit 130 may apply a signal to the bit line BL based on a data signal DATA received from the peripheral circuit 140 in response to the page buffer control signal PB_C, and may write data to the memory cell of the memory cell array 110 accordingly. The page buffer circuit 130 may write data to the memory cell connected to the word line activated by the row decoder 120, or read data therefrom.

The peripheral circuit 140 may receive a command signal CMD, an address signal ADD, and a control signal CTRL from one or more devices outside of the memory device 100, and may transmit and receive data DATA with one or more devices outside of the memory device 100. For example, the one or more outside devices may be a memory controller. The peripheral circuit 140 may output signals for writing data to the memory cell array 110 or reading data from the memory cell array 110, such as a row address X_A and a page buffer control signal PB_C, based on a command signal CMD, an address signal ADD, and a control signal CTRL. The peripheral circuit 140 can generate various voltages required in the memory device 100, including an operating voltage X_V.

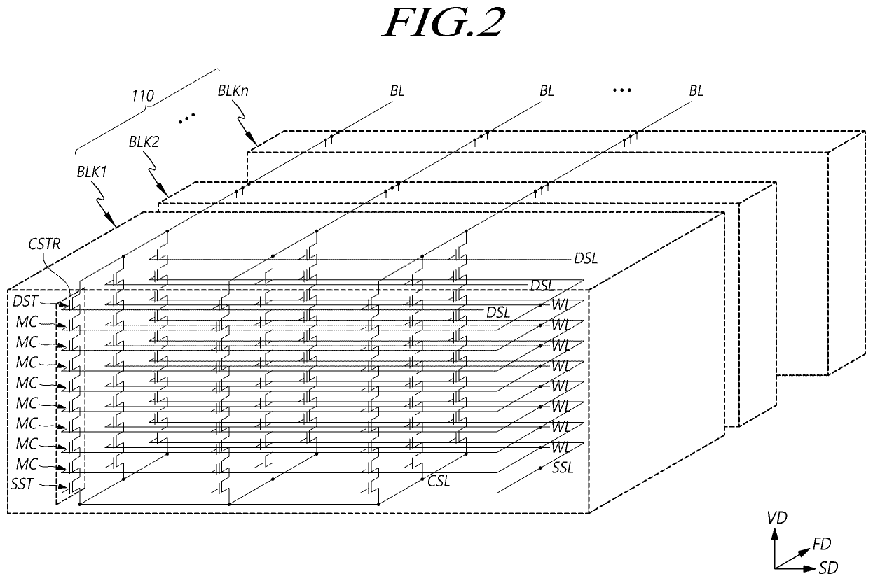

FIG. 2 illustrates an equivalent circuit diagram of the memory cell array 110 illustrated in FIG. 1.

Referring to FIG. 2, each of the memory blocks BLK1-BLKn may include a plurality of cell strings CSTR connected between a plurality of bit lines BL and a common source line CSL.

Each of the bit lines BL may extend in a first direction FD. The bit lines BL may be arranged spaced apart from each other at regular intervals along a second direction SD. A plurality of cell strings CSTR may be connected in parallel to each of the bit lines BL. The cell strings CSTR may be commonly connected to the common source line CSL. A plurality of cell strings CSTR may be arranged between the plurality of bit lines BL and one common source line CSL.

Each of the cell strings CSTR may include a drain select transistor DST connected to the bit line BL, a source select transistor SST connected to the common source line CSL, and a plurality of memory cells MC connected between the drain select transistor DST and the source select transistor SST. The drain select transistor DST, the memory cells MC and the source select transistor SST may be connected in series along a third direction VD.

The drain select line DSL, a plurality of word lines WL and the source select line SSL may be arranged along a third direction VD between bit lines BL and a common source line CSL. The drain select lines DSL may be respectively connected to the gates of the corresponding drain select transistors DST. The word lines WL may be respectively connected to the gates of the corresponding memory cells MC. The source select line SSL may be connected to the gates of the source select transistors SST. The memory cells MC commonly connected to one word line WL may constitute one page.

The bit lines BL and the common source line CSL may be commonly connected to the memory blocks BLK1-BLKn. That is, the memory blocks BLK1-BLKn may share bit lines BLs and a common source line CSL. The drain select lines DSLs, the plurality of word lines WLs, and the source select line SSL may be individually provided to each of the memory blocks BLK1-BLKn.

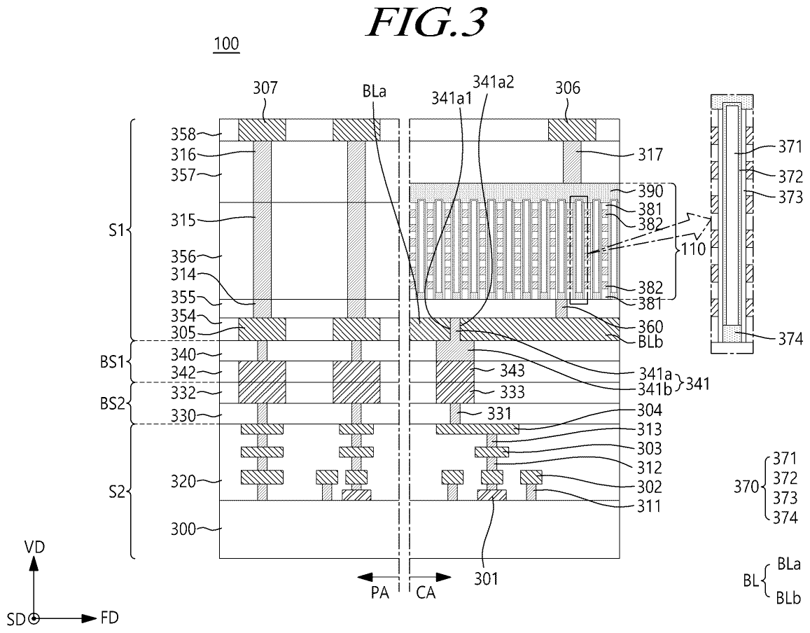

FIG. 3 illustrates a cross-sectional structure of a memory device according to an embodiment of the present disclosure.

Referring to FIG. 3, the memory device 100 according to the embodiments of the present disclosure may include a cell area CA and a peripheral area PA. Memory cell array 110 may be disposed in the cell area CA. The peripheral area PA may be disposed adjacent or around the cell area CA. Circuits and wirings for transmitting signals to the memory cell array 110 or various circuits and wirings for connecting the memory device 100 to an external device may be arranged in the peripheral area PA.

The memory device 100 may include a first semiconductor structure S1, a second semiconductor structure S2, a first bonding structure BS1 adjacent to the first semiconductor structure, and a second bonding structure BS2 adjacent to the second semiconductor structure. The first bonding structure BS1 and the second bonding structure BS2 may be located between the first and second semiconductor structures S1 and S2. The first bonding structure BS1 and the second bonding structure BS2 may be bonded to each other. Specifically, the lower surface of the first bonding structure BS1 may be bonded to the upper surface of the second bonding structure BS2. The boundary between the first bonding structure BS1 and the second bonding structure BS2 may be referred to as a bonding interface.

The second semiconductor structure S2 of the memory device 100 may include a first substrate 300, a gate 301, wirings 302, 303 and 304, contacts 311, 312 and 313, and a first insulating layer 320. The first insulating layer 320 may be formed over the first substrate 300.

The first substrate 300 may include a semiconductor substrate such as a silicon wafer or a silicon-on-insulator (SOI) wafer. The first substrate 300 may include a III-V group semiconductor substrate, for example, a compound semiconductor substrate such as GaAs. The first substrate 300 may include single crystal silicon, polysilicon, amorphous silicon, single crystal silicon germanium, polycrystalline silicon germanium, carbon-doped silicon, or a combination thereof.

The gate 301, the contacts 311, 312 and 313, the wirings 302, 303 and 304, and the first insulating layer 320 may be disposed on the first substrate 300. The contacts 311, 312 and 313 may be arranged between the wirings 302, 303 and 304, or between a first wiring 302 and the first substrate 300. The contacts 311, 312 and 313 may be electrically connected to the wirings 302, 303 and 304. The gate 301, a first contact 311, and the first wiring 302 may constitute one transistor. In an embodiment, the gate 301, the first contact 311, and the first wiring 302 may constitute a transistor included in the page buffer PB illustrated in FIG. 1.

The gate 301, the contacts 311, 312 and 313, and the wirings 302, 303 and 304 may include a conductive material such as a metal, a metal oxide, a metal nitride, a metal silicide, polysilicon, a conductive carbon, or a combination thereof. The first insulating layer 320 may include silicon oxide, silicon nitride, silicon oxynitride, a high-k dielectric, or a combination thereof. The gate 301, the contacts 311, 312 and 313, and the wirings 302, 303 and 304 may be formed in the first insulating layer 320.

The second bonding structure BS2 may be disposed on the second semiconductor structure S2. The second bonding structure BS2 may include a second insulating layer 330, a second bonding contact 331, a second bonding insulating layer 332, and a second bonding pad 333.

The second bonding contact 331 may be disposed in the second insulating layer 330. The second bonding contact 331 may be connected to a corresponding third wiring 304. The second bonding insulating layer 332 may be disposed on the second bonding contact 331 and the second insulating layer 330. The second bonding pad 333 may be arranged in the second bonding insulating layer 332. The second bonding pad 333 may be connected to a corresponding second bonding contact 331. The upper surface of the second bonding pad 333 may be coplanar or substantially coplanar with the upper surface of the second bonding insulating layer 332. Stated differently, the upper surface of the second bonding pad 333 may form the same or substantially the same plane as the upper surface of the second bonding insulating layer 332.

The first bonding structure BS1 may be disposed on the second bonding structure BS2. The first bonding structure BS1 may include a third insulating layer 340, a first bonding contact 341, a first bonding insulating layer 342, and a first bonding pad 343.

The first bonding insulating layer 342 may be disposed on the second bonding insulating layer 332. The first bonding pad 343 may be disposed within the first bonding insulating layer 342. The lower surface of the first bonding pad 343 may form substantially the same plane as the lower surface of the first bonding insulating layer 342. The lower surface of the first bonding pad 343 may contact the upper surface of a corresponding second bonding pad 333. In an embodiment, the first bonding pad 343 may be bonded to the second bonding pad 333. The lower surface of the first bonding insulating layer 342 may contact the lower surface of the second bonding insulating layer 332. In an embodiment, the first bonding insulating layer 342 may be bonded to the second bonding insulating layer 332.

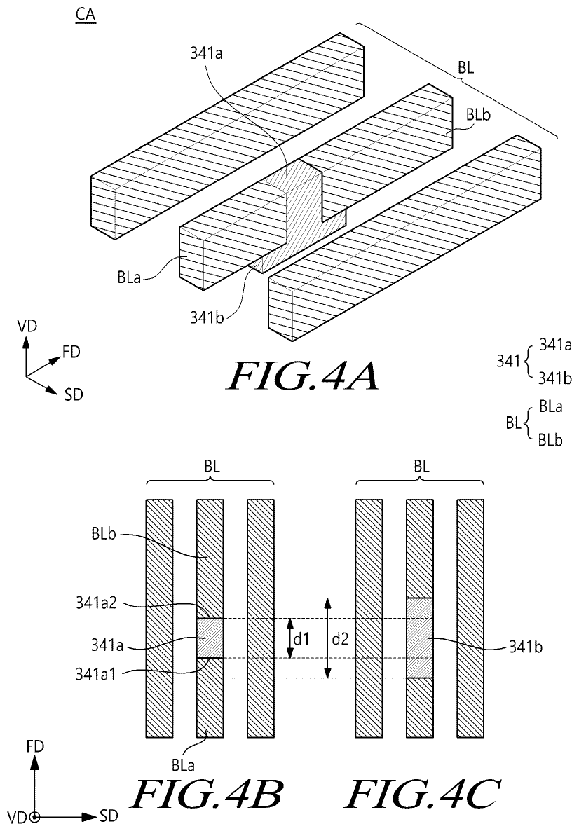

The third insulating layer 340 and the first bonding contact 341 may be disposed on the first bonding pad 343 and the first bonding insulating layer 342. At least a portion of the first bonding contact 341 may be disposed within the third insulating layer 340. The first bonding contact 341 may be connected to a corresponding first bonding pad 343. The first bonding contact 341 disposed in the cell area CA may include a portion protruding in a vertical direction more than an upper surface of the first bonding contact 341 disposed in the peripheral area PA. The first bonding contact 341 disposed in the cell area CA may include a first portion 341a and a second portion 341b positioned below the first portion 341a. The first portion 341a and the second portion 341b of the first bonding contact 341 will be described later in more detail with reference to FIG. 4A to FIG. 4C.

The first bonding contact 341, the second bonding contact 331, the first bonding pad 343 and the second bonding pad 333 may include a conductive material such as a metal, a metal oxide, a metal nitride, a metal silicide, polysilicon, a conductive carbon, or a combination thereof. The second insulating layer 330, the third insulating layer 340, the first bonding insulating layer 342, and the second bonding insulating layer 332 may include silicon oxide, silicon nitride, silicon oxynitride, a high-k dielectric, or a combination thereof. In an embodiment, the first bonding insulating layer 342 and the second bonding insulating layer 332 may include silicon carbon nitride.

The first semiconductor structure S1 may be disposed on the first bonding structure BS1. The first semiconductor structure S1 may include wirings 305, 306 and 307, contacts 314, 315, 316 and 317, a fourth insulating layer 354, a fifth insulating layer 355, a sixth insulating layer 356, a seventh insulating layer 357, an eighth insulating layer 358, a bit line contact 360, and a memory cell array 110.

In the cell area CA, a bit line BL may be disposed on the third insulating layer 340. The bit line BL may extend in the first direction FD. The bit line BL may include a first portion BLa which contacts one side of the first portion 341a of the first bonding contact 341, and a second portion BLb which contacts the other side opposite to the one side of the first portion 341a of the first bonding contact 341. The first portion BLa and the second portion BLb of the bit line BL will be described later with reference to FIG. 4A to FIG. 4C.

The bit line contact 360 and the fifth insulating layer 355 may be disposed to the bit line BL. The memory cell array 110 may be disposed on the bit line contact 360 and the fifth insulating layer 355.

The memory cell array 110 may include an interlayer insulating layer 381 and an electrode layer 382 alternately stacked in a vertical direction, a channel structure 370, and a source plate 390.

The channel structure 370 may penetrate the interlayer insulating layer 381 and the electrode layer 382 in a vertical direction. The channel structure 370 may extend into the source plate 390 in the vertical direction. The upper surface of the channel structure 370 may be positioned higher than the lower surface of the source plate 390 in the vertical direction. The lower surface of the channel structure 370 may be substantially the same plane as the lower surface of the interlayer insulating layer 381 disposed at the lowest portion of the memory cell array 110.

The channel structure 370 may be connected to a corresponding bit line contact 360. The channel structure 370 may be connected to the second semiconductor structure S2 via a corresponding bit line contact 360, the bit line BL, the first bonding contact 341 corresponding to the bit line BL, the first bonding pad 343 corresponding to the first bonding contact 341, the second bonding pad 333 connected to the first bonding pad 343, and the second bonding contact 331 corresponding to the second bonding pad 333.

The channel structure 370 may include a core layer 371, a channel pattern 372, a gate insulating layer 373, and a drain pad 374. The drain pad 374 may contact an upper surface of the bit line contact 360. The core layer 371 may be disposed on the drain pad 374. The core layer 371 may extend in a vertical direction. The channel pattern 372 may surround a side surface and a lower surface of the core layer 371. The channel pattern 372 may extend into the inside of the source plate 390 in the vertical direction. The gate insulating layer 373 may surround the side surfaces of the channel pattern 372 and the drain pad 374. One electrode layer 382, the gate insulating layer 373, and a portion of the channel pattern 372 overlapping with one electrode layer 382 in a first direction FD or a second direction SD may constitute one memory cell.

The source plate 390 may be disposed on the interlayer insulating layer 381 and the channel structure 370 located at the top of the memory cell array 110. The source plate 390 may be connected to the common source line CSL illustrated in FIG. 2.

The seventh insulating layer 357 and a seventh contact 317 may be disposed on the source plate 390. The seventh contact 317 may be connected to the source plate 390 by penetrating the seventh insulating layer 357 in a vertical direction. The eighth insulating layer 358 and a fifth wiring 306 may be disposed on the seventh insulating layer 357 and the seventh contact 317. The fifth wiring 306 may be connected to a seventh contact 317 by penetrating the eighth insulating layer 358 in a vertical direction.

The bit line BL, the bit line contact 360, the electrode layer 382, the drain pad 374, the seventh contact 317, and the fifth wiring 306 may include a conductive material such as a metal, a metal oxide, a metal nitride, a metal silicide, polysilicon, a conductive carbon, or a combination thereof. The channel pattern 372 and the source plate 390 may include a semiconductor material such as polysilicon. The fifth insulating layer 355, the interlayer insulating layer 381, the seventh insulating layer 357, and the eighth insulating layer 358 may include silicon oxide, silicon nitride, silicon oxynitride, a low-k dielectric, a high-k dielectric, or a combination thereof.

In the peripheral area PA, a fourth wiring 305 and a fourth insulating layer 354 may be disposed on the third insulating layer 340. A fourth contact 314, a fifth contact 315, and a sixth contact 316 may be sequentially stacked on the fourth wiring 305. A sixth wiring 307 may be connected to a corresponding sixth contact 316. The sixth contact 316 may be connected to the fifth contact 315. The fifth contact 315 may be connected to the fourth contact 314. The fourth contact 314 may be connected to a corresponding fourth wiring 305. The fourth wiring 305, the sixth wiring 307, the fourth contact 314, the fifth contact 315, and the sixth contact 316 may include a conductive material such as a metal, a metal oxide, a metal nitride, a metal silicide, polysilicon, conductive carbon, or a combination thereof. The fourth insulating layer 354 and the sixth insulating layer 356 may include silicon oxide, silicon nitride, silicon oxynitride, a low-k dielectric, a high-k dielectric, or a combination thereof.

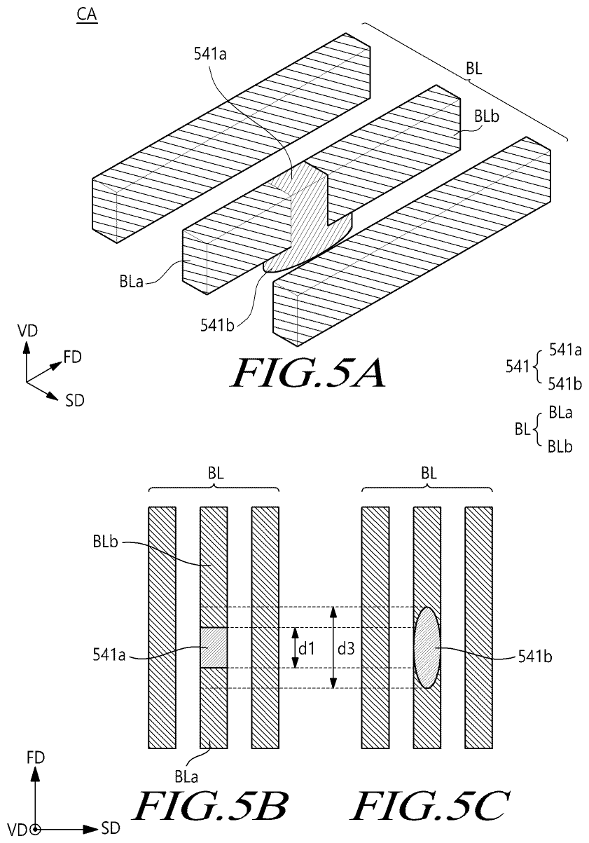

FIG. 4A to FIG. 4C and FIG. 5A to FIG. 5C illustrate embodiments of a three-dimensional structure and a planar structure of the memory device illustrated in FIG. 3.

FIG. 4A and FIG. 5A illustrates an embodiment of a three-dimensional structure of a bit line BL and a first bonding contact 341 and 541. FIG. 4B and FIG. 5B is a diagram looking down on the bit line BL and the first bonding contact 341 and 541 from the upper surface of the bit line BL. FIG. 4C and FIG. 5C is a drawing looking up on the bit line BL and the first bonding contact 341 and 541 from below the lower surface of the bit line BL.

Referring to FIG. 4A to FIG. 4C, the first bonding contact 341 may include a first portion 341a and a second portion 341b. The bit line BL may include a first portion BLa and a second portion BLb. The first bonding contact 341 may correspond to one bit line BL. A plurality of bit lines BL may be connected to a corresponding first bonding contact 341, respectively.

The first portion 341a of the first bonding contact 341 may penetrate the corresponding one bit line BL in the vertical direction. The first portion 341a of the first bonding contact 341 may be located between the first portion BLa and the second portion BLb of the corresponding one bit line BL. One side 341a1 of the first portion 341a of the first bonding contact 341 may contact the first portion BLa of the bit line BL. The first portion 341a of the first bonding contact 341 and the other portion 341a2 opposite to the one side 341a1 may contact the second portion BLb of the bit line BL. The first portion 341a of the first bonding contact 341 may overlap with the first portion BLa and the second portion BLb of the bit line BL in the first direction FD. In FIG. 4A to FIG. 4C, one first bonding contact 341 penetrating one bit line BL is illustrated, but each of the first bonding contacts 341 may penetrate one corresponding bit line BL in the vertical direction.

The first portion BLa and the second portion BLb of the bit line BL may be spaced apart in the first direction FD. The first portion BLa and the second portion BLb of the bit line BL may overlap with each other in the first direction FD. The first portion BLa and the second portion BLb of the bit line BL may be electrically connected through the first bonding contact 341.

The second portion 341b of the first bonding contact 341 may be located below the first portion 341a. The second portion 341b of the first bonding contact 341 may be continuous to the first portion 341a. The upper surface of the second portion 341b of the first bonding contact 341 may contact the lower surfaces of the first portion BLa and the second portion BLb of the bit line BL. The width d2 of the second portion 341b of the first bonding contact 341 in the first direction FD may be greater than the width d1 of the first portion 341a of the first bonding contact 341 in the first direction FD. In an embodiment, the width d2 of the second portion 341b of the first bonding contact 341 in the first direction FD may be substantially equal to the width of the first bonding pad 343 in the first direction FD. In an embodiment, the width d2 of the second portion 341b of the first bonding contact 341 in the first direction FD may be 400 nm, for example.

Referring to FIG. 5A to FIG. 5C, a first bonding contact 541 may include a first portion 541a and a second portion 541b. The first portion 541a of the first bonding contact 541 may have the same shape as the first portion 341a described with reference to FIG. 4A to FIG. 4C. The second portion 541b of the first bonding contact 541 may be continuous to the first portion 541a.

In an embodiment, the second portion 541b of the first bonding contact 541 may have a cylindrical shape. For example, the upper surface and the lower surface of the second portion 541b of the first bonding contact 541 may be ellipses having substantially the same area.

The upper surface of the second portion 541b of the first bonding contact 541 may contact the lower surface of the first portion BLa and the second portion BLb of the bit line BL. The largest width d3 of the width of the second portion 541b of the first bonding contact 541 in the first direction FD may be greater than the width d1 of the first portion 541a of the first bonding contact 541 in the first direction FD.

The upper surface and the lower surface of the second portion 341b and 541b of the first bonding contact 341 and 541 described with reference to FIG. 4A to FIG. 4C and FIG. 5A to FIG. 5C are not limited to a square or an ellipse, and may have various shapes.

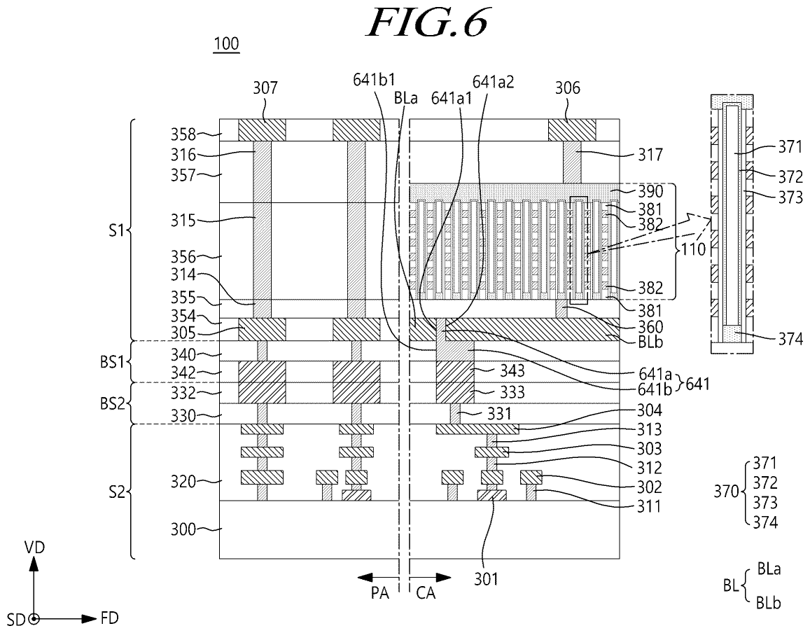

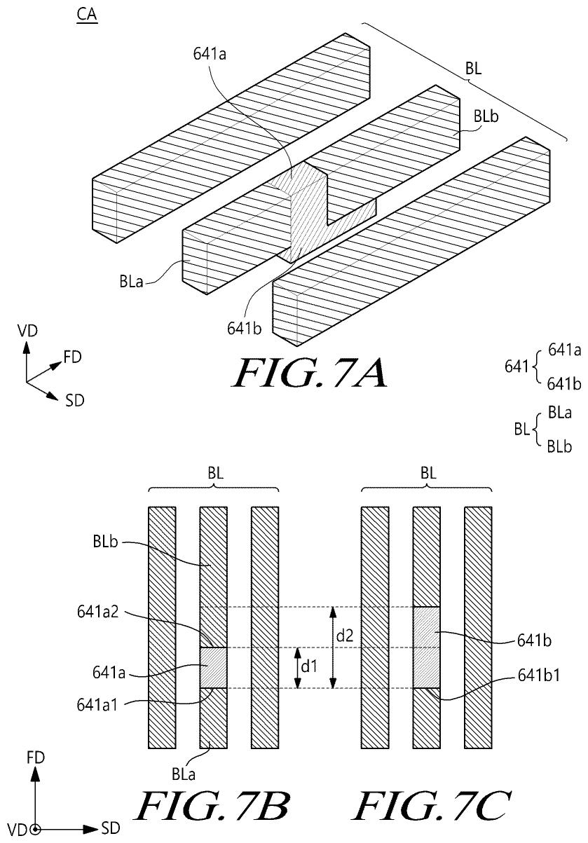

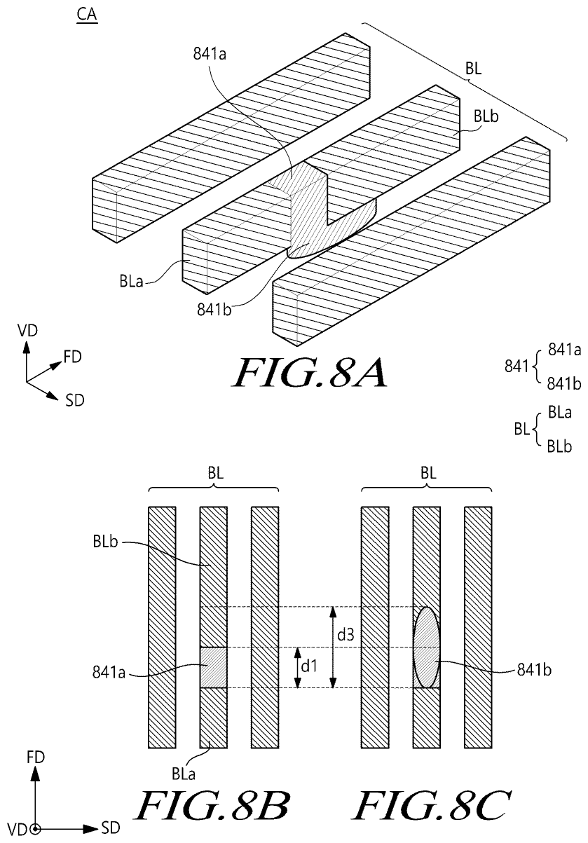

FIG. 6 illustrates another cross-sectional structure of a memory device according to an embodiment of the present disclosure. FIG. 7A to FIG. 7C and FIG. 8A to FIG. 8C illustrate embodiments of a three-dimensional structure and a planar structure of the memory device illustrated in FIG. 6.

Hereinafter, descriptions of configurations which are substantially the same as those of the previous embodiments may be omitted.

Referring to FIG. 6 and FIG. 7A to 7C, a memory device 100 according to an embodiment of the present disclosure may include a first semiconductor structure S1, a second semiconductor structure S2, a first bonding structure BS1, and a second bonding structure BS2. The second semiconductor structure S2 may include a first substrate 300, and a first insulating layer 320 formed over the first substrate 300. The second semiconductor structure S2 may further include a gate 301, wirings 302, 303 and 304, and contacts 311, 312 and 313 formed in the first insulating layer 320. The second bonding structure BS2 may include a second insulating layer 330, a second bonding contact 331, a second bonding insulating layer 332, and a second bonding pad 333. The first bonding structure BS1 may include a third insulating layer 340, a first bonding contact 641, a first bonding insulating layer 342, and a first bonding pad 343. The first semiconductor structure S1 may include wirings 305, 306 and 307, contacts 314, 315, 316 and 317, a fourth insulating layer 354, a fifth insulating layer 355, a sixth insulating layer 356, a seventh insulating layer 357, an eighth insulating layer 358, a bit line contact 360, and a memory cell array 110.

FIG. 7A and FIG. 8A illustrate embodiments of three-dimensional structures of a bit line BL and a first bonding contact 641 and 841. FIG. 7B and FIG. 8B are diagrams looking down on the bit line BL and the first bonding contact 641 and 841 from the upper surface of the bit line BL. FIG. 7C and FIG. 8C are diagrams looking up on the bit line BL and the first bonding contact 641 and 841 from below the lower surface of the bit line BL.

Referring to FIG. 7A to FIG. 7C, the first bonding contact 641 may include a first portion 641a and a second portion 641b. The bit line BL may include a first portion BLa and a second portion BLb with the first portion 641a of the first bonding contact 641 disposed between the first and second portions BLa, BLb of the bit line BL.

The first portion 641a of the first bonding contact 641 may penetrate the bit line BL in the vertical direction. The first portion 641a of the first bonding contact 641 may be located between the first portion BLa and the second portion BLb of the bit line BL. One side 641a1 of the first portion 641a of the first bonding contact 641 may contact the first portion BLa of the bit line BL. The other side 641a2 of the first portion 641a of the first bonding contact 641 opposite to the one side 641a1 may contact the second portion BLb of the bit line BL. The first portion 641a of the first bonding contact 641 may overlap with the first portion BLa and the second portion BLb of the bit line BL in the first direction FD.

The first portion BLa and the second portion BLb of the bit line BL may be spaced apart in the first direction FD. The first portion BLa and the second portion BLb of the bit line BL may overlap with each other in the first direction FD. The first portion BLa and the second portion BLb of the bit line BL may be electrically connected through the first bonding contact 641.

The second portion 641b of the first bonding contact 641 may be located below the first portion 641a. The second portion 641b of the first bonding contact 641 may be continuous to the first portion 641a. The upper surface of the second portion 641b of the first bonding contact 641 may contact the lower surface of the second portion BLb of the bit line BL. The width d2 of the second portion 641b of the first bonding contact 641 in the first direction FD may be greater than the width d1 of the first portion 641a of the first bonding contact 641 in the first direction FD.

In an embodiment, one side 641b1 of the second portion 641b of the first bonding contact 641 may be coplanar or substantially coplanar with the one side 641a1 of the first portion 641a of the first bonding contact 641. Stated differently, in an embodiment, one side 641b1 of the second portion 641b of the first bonding contact 641 may form substantially the same plane as one side 641a1 of the first portion 641a of the first bonding contact 641. In an embodiment, the second portion 641b of the first bonding contact 641 may not overlap with the first portion BLa of the bit line BL. For example, the upper surface of the second portion 641b of the first bonding contact 641 may not contact the lower surface of the first portion BLa of the bit line BL.

Referring to FIG. 8A to FIG. 8C the first bonding contact 841 may include a first portion 841a and a second portion 841b. The first portion 841a of the first bonding contact 841 may have the same shape as the first portion 641a described with reference to FIG. 7A to FIG. 7C. The second portion 841b of the first bonding contact 841 may be continuous to the first portion 841a.

In an embodiment, the second portion 841b of the first bonding contact 841 may have a cylindrical shape. For example, the upper surface and the lower surface of the second portion 841b of the first bonding contact 841 may be ellipses having substantially the same area.

The upper surface of the second portion 841b of the first bonding contact 841 may contact the lower surface of the second portion BLb of the bit line BL. The second portion 841b of the first bonding contact 841 may not overlap with the first portion BLa of the bit line BL. In an embodiment, the upper surface of the second portion 841b of the first bonding contact 841 may not contact the lower surface of the first portion BLa of the bit line BL.

The largest width d3 of the width of the second portion 841b of the first bonding contact 841 in the first direction FD may be greater than the width d1 of the first portion 841a of the first bonding contact 841 in the first direction FD.

The upper and lower surfaces of the second portions 641b and 841b of the first bonding contacts 641 and 841 described with reference to FIG. 7A to FIG. 7C and FIG. 8A to FIG. 8C are not limited to squares or ovals, and may have various shapes.

FIG. 9 to FIG. 16 illustrate a method for manufacturing a memory device according to an embodiment of the present disclosure.

Referring to FIG. 9, there may be prepared a second substrate 900. The second substrate 900 may include a semiconductor substrate such as a silicon wafer or a Silicon-On-Insulator (SOI) wafer. The second substrate 900 may include, for example, a III-V group semiconductor substrate, a compound semiconductor substrate such as GaAs. The second substrate 900 may include single crystal silicon, polysilicon, amorphous silicon, single crystal silicon germanium, polycrystalline silicon germanium, carbon-doped silicon, or a combination thereof.

A plurality of interlayer insulating layers 381 and electrode layers 382 may be alternately laminated or stacked over the second substrate 900 in the cell area CA. A plurality of channel structures 370 may be formed each one to penetrate the interlayer insulating layers 381 and the electrode layers 382 in a vertical direction. A sixth insulating layer 356 may be formed on the second substrate 900 in the peripheral area PA. After the sixth insulating layer 356 is formed, a fifth contact 315 penetrating the sixth insulating layer 356 may be formed. More than one fifth contacts 315 may be formed. A fifth insulating layer 355 may be formed on the sixth insulating layer 356, the channel structures 370, and the uppermost interlayer insulating layer 381. At least one bit line contact 360 penetrating the fifth insulating layer 355 may be formed in the cell area CA. The bit line contact 360 may be connected to a corresponding one of the channel structures 370. A fourth contact 314 penetrating the fifth insulating layer 355 may be formed in the peripheral area PA to contact the top surface of the fifth contact 315.

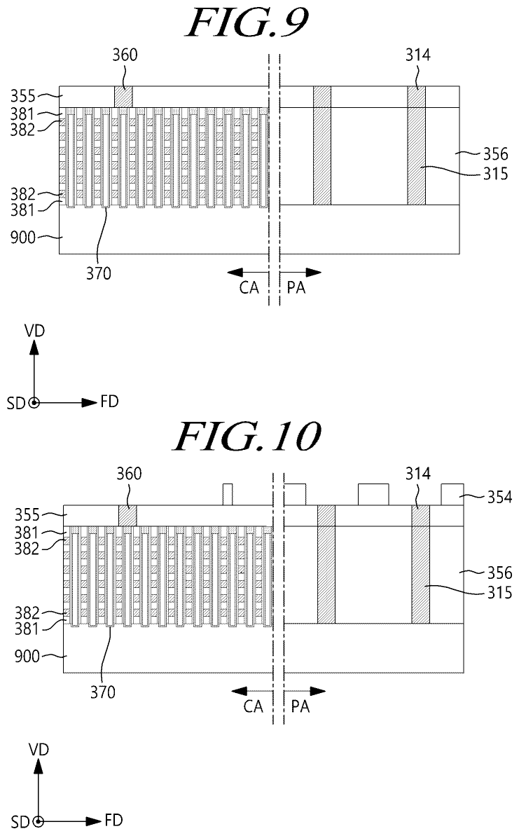

Referring to FIG. 10, a fourth insulating layer 354 may be formed on the fifth insulating layer 355. The process of forming the fourth insulating layer 354 may include an etching process. For example, the process of forming the fourth insulating layer 354 may include a process of applying an insulating material on the cell area CA and the peripheral area PA, and then removing a portion of the insulating material. At least a portion of the fourth insulating layer 354 may be formed in the cell area CA. For example, in the above embodiment, at least a portion of the insulating material may remain in the cell area CA.

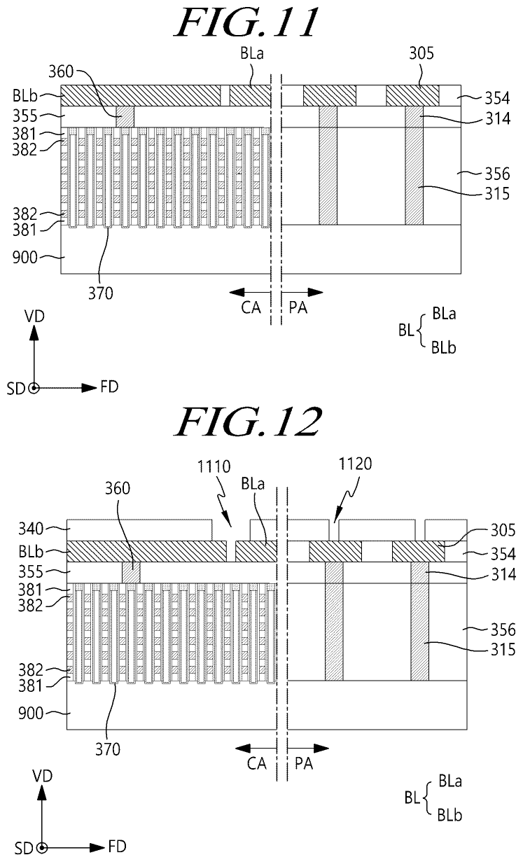

Referring to FIG. 11, a bit line BL may be formed in the cell area CA. The bit line BL may be formed around the fourth insulating layer 354. The upper surface of the bit line BL may be coplanar or substantially coplanar with the upper surface of the fourth insulating layer 354. In an embodiment, the process of forming the bit line BL may include a process of depositing a conductive material. A first portion BLa and a second portion BLb of the bit line BL may be spaced apart from each other in the first direction FD. The fourth insulating layer 354 may be positioned between the first portion BLa and the second portion BLb of the bit line BL.

A fourth wiring 305 may be formed in the peripheral area PA to fill the space between the fourth insulating layer 354. In an embodiment, the fourth wiring 305 may include the same material as the material forming the bit line BL.

Referring to FIG. 12, a third insulating layer 340 may be formed on the bit line BL, the fourth insulating layer 354, and the fourth wiring 305. After the third insulating layer 340 is formed, through holes 1110 and 1120 penetrating the third insulating layer 340 may be formed. The process of forming the through holes 1110 and 1120 may include an etching process.

A first through hole 1110 may be formed in the cell area CA. The process of forming the first through hole 1110 may include a process of removing the fourth insulating layer 354 located between the first portion BLa and the second portion BLb of the bit line BL. A second through hole 1120 may be formed in the peripheral area PA. The process of forming the second through hole 1120 may include a process of removing the third insulating layer 340.

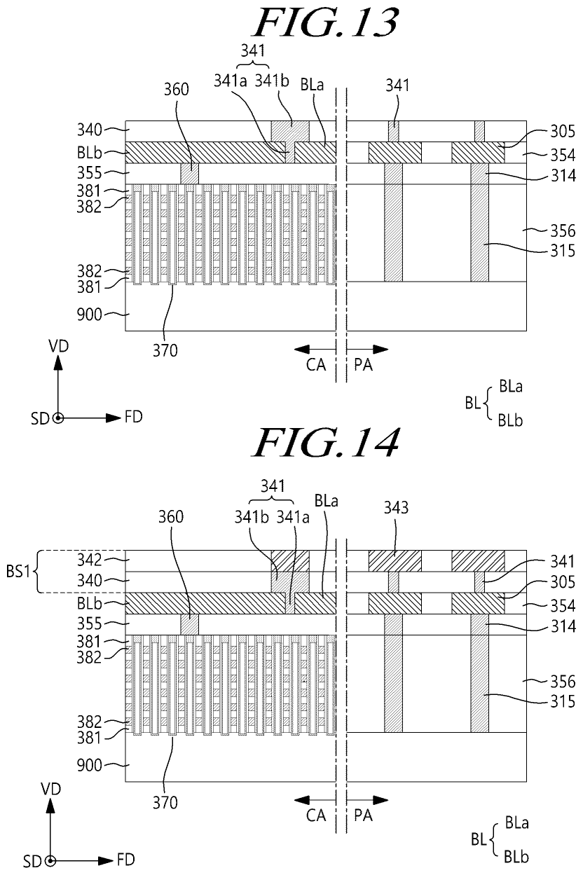

Referring to FIG. 3, FIG. 12, and FIG. 13, a first bonding contact 341 may be formed to fill the first and second through holes 1110 and 1120. The first bonding contact 341 formed in the cell area CA may include a first portion 341a and a second portion 341b. The first portion 341a of the first bonding contact 341 may fill the space between the first portion BLa and the second portion BLb of the bit line BL. The second portion 341b of the first bonding contact 341 may fill the space between the third insulating layer 340.

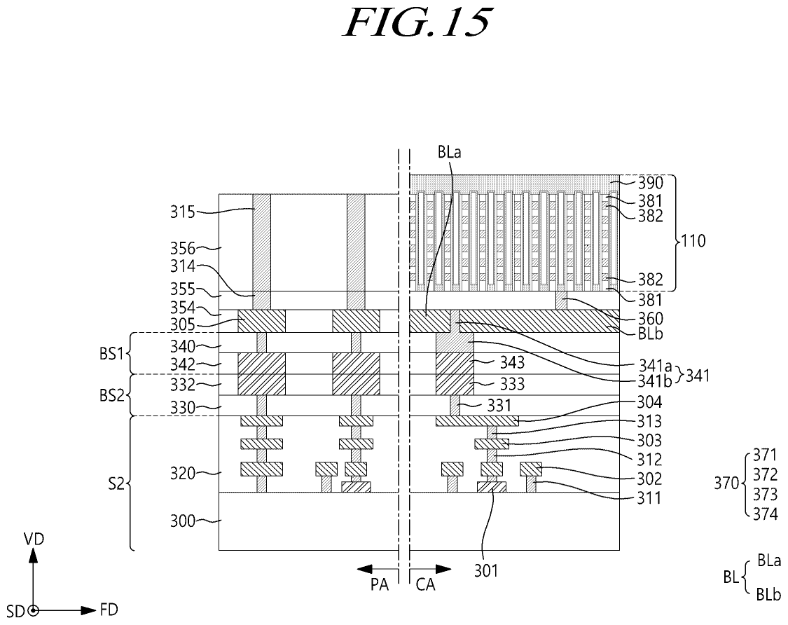

Referring to FIG. 14, a first bonding insulating layer 342 and a first bonding pad 343 may be formed on the third insulating layer 340 and the first bonding contact 341. The first bonding pad 343 may be formed to fill the space between the first bonding insulating layer 342. The upper surface of the first bonding pad 343 may be coplanar or substantially coplanar with the upper surface of the first bonding insulating layer 342.

Referring to FIG. 15, a second semiconductor structure S2 and a second bonding structure BS2 may be prepared. The second bonding structure BS2 may be formed on the second semiconductor structure S2. The lower surface of the first bonding structure BS1 may be bonded to the upper surface of the second bonding structure BS2. The lower surface of the first bonding pad 343 may contact the upper surface of the second bonding pad 333. The lower surface of the first bonding insulating layer 342 may contact the upper surface of the second bonding insulating layer 332.

After the first bonding structure BS1 is bonded to the second bonding structure BS2, the first substrate 900 may be removed. In an embodiment, the process of removing the first substrate 900 may include a grinding process or a chemical mechanical polishing (CMP) process. After the first substrate 900 is removed, a source plate 390 may be formed on the channel structures 370 and the interlayer insulating layer 381 of the cell area CA.

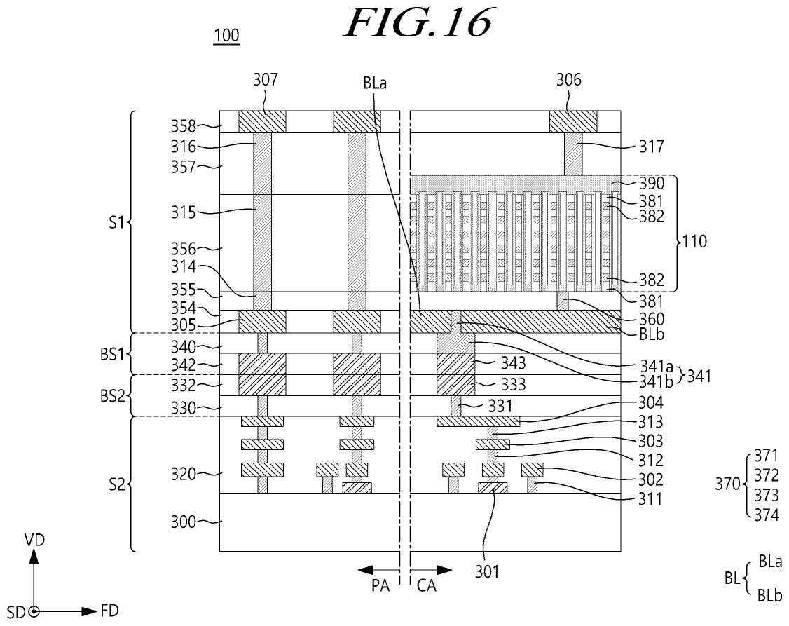

Referring to FIG. 16, a seventh insulating layer 357 may be formed on the sixth insulating layer 356 and the source plate 390. Thereafter, a sixth contact 316 and a seventh contact 317 penetrating the seventh insulating layer 357 may be formed. An eighth insulating layer 358 may be formed on the sixth contact 316 and the seventh contact 317. Thereafter, a fifth wiring 306 and a sixth wiring 307 penetrating the eighth insulating layer 358 may be formed to contact the seventh contact 317 and the sixth contact 316 respectively.

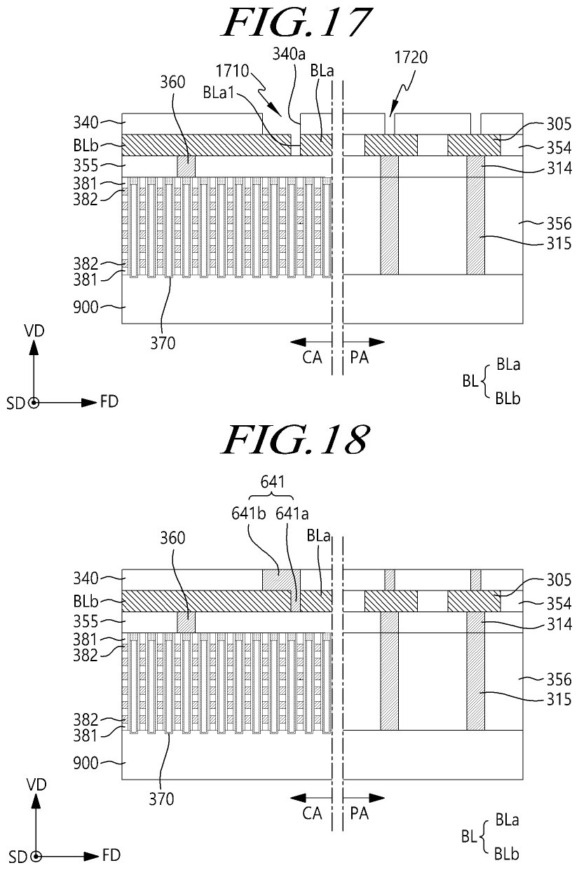

FIG. 17 and FIG. 18 illustrate other methods for manufacturing a memory device according to an embodiment of the present invention.

The memory device illustrated in FIG. 17 may be formed in the same manner as the memory device described with reference to FIG. 11.

Referring to FIG. 17, a third insulating layer 340 may be formed on a bit line BL, a fourth insulating layer 354, and a fourth wiring 305. After the third insulating layer 340 is formed, through holes 1710 and 1720 may be formed to penetrate the third insulating layer 340. The process of forming the through holes 1710 and 1720 may include an etching process.

A first through hole 1710 may be formed in the cell area CA. The process of forming the first through hole 1710 may include a process of removing the fourth insulating layer 354 located between the first portion BLa and the second portion BLb of the bit line BL. A second through hole 1720 may be formed in the peripheral area PA. The process of forming the second through hole 1720 may include a process of removing the third insulating layer 340. In an embodiment, one side BLa1 of the first portion BLa of the bit line BL contacting the first through hole 1710 may form substantially the same plane as one side surface 340a of the third insulating layer 340 contacting the first through hole 1710.

Referring to FIG. 6, FIG. 17, and FIG. 18, a first bonding contact 641 may be formed to fill the first and second through holes 1710 and 1720. The first bonding contact 641 formed in the cell area CA may include a first portion 641a and a second portion 641b. The first portion 641a of the first bonding contact 641 may fill the space between the first portion BLa and the second portion BLb of the bit line BL. The second portion 641b of the first bonding contact 641 may fill the space between the third insulating layer 340.

Referring again to FIG. 3, the memory device 100 according to an embodiment of the present disclosure may include the first bonding contact 341. The first bonding contact 341 may include a first portion 341a and a second portion 341b. The first portion 341a of the first bonding contact 341 may penetrate the inside of the bit line BL in the vertical direction. The side surface of the bit line BL may contact the first portion 341a of the first bonding contact 341. The lower surface of the bit line BL may contact the second portion 341b of the first bonding contact 341.

According to the embodiments of the present disclosure, as the area where the first bonding contact 341 contacts the bit line BL increases, it is possible to prevent a defect which may occur due to high contact resistance between the first bonding contact 341 and the bit line BL. Specifically, in the case that the first bonding contact 341 vertically penetrates the inside of the bit line BL, the contact area between the first bonding contact 341 and the bit line BL may increase by the area of the side surface of the first portion 341a of the first bonding contact 341 contacting the bit line BL. Since the contact resistance decreases as the contact area increases, the contact resistance between the first bonding contact 341 and the bit line BL may decrease. Accordingly, it is possible to suppress a defect due to an increase in contact resistance. According to an embodiment of the present disclosure, it is possible to prevent deterioration of the device characteristics of a memory device due to a process defect.

The above description and the accompanying drawings provide embodiments of the technical concept of the present disclosure for illustrative purposes only. Various modifications, additions and substitutions to the described embodiments will be readily apparent to those skilled in the art without departing from the spirit and scope of the present disclosure. In addition, since the embodiments disclosed in this disclosure are not intended to limit the technical concept of this disclosure but to describe the technical concept of this disclosure, the scope of the technical concept of this disclosure is not limited by these embodiments. The protection scope of this disclosure should be interpreted by the claims below, and all technical concepts within the equivalent scope should be interpreted as being included in the scope of the rights of this disclosure. Furthermore, the embodiments may be combined to form additional embodiments.

What is claimed is:

1. A memory device comprising:
a first semiconductor structure including a bit line extending in a first direction;
a second semiconductor structure disposed below the first semiconductor structure;
a first bonding structure disposed between the first semiconductor structure and the second semiconductor structure, and including a first bonding insulating layer, a first bonding pad disposed within the first bonding insulating layer, and a first bonding contact connected to the first bonding pad; and
a second bonding structure disposed between the first bonding structure and the second semiconductor structure, and including a second bonding insulating layer, a second bonding pad disposed within the second bonding insulating layer and having an upper surface in contact with a lower surface of the first bonding pad, and a second bonding contact connected to the second bonding pad,
wherein the first bonding contact penetrates the bit line in a direction perpendicular to the first direction.

2. The memory device of claim 1, wherein the bit line includes a first portion contacting one side of the first bonding contact and a second portion contacting the other side opposite the one side of the first bonding contact,
wherein the first portion of the bit line is spaced apart from the second portion of the bit line.

3. The memory device of claim 2, wherein the first portion of the bit line and the second portion of the bit line are electrically connected.

4. The memory device of claim 1, wherein the first bonding contact includes a first portion located within the bit line and a second portion located below the bit line,
wherein a width of the second portion of the first bonding contact in the first direction is greater than a width of the first portion of the first bonding contact in the first direction.

5. The memory device of claim 4, wherein a side of the first portion of the first bonding contact is in contact with the bit line.

6. The memory device of claim 4, wherein an upper surface of the second portion of the first bonding contact is in contact with the bit line.

7. The memory device of claim 4, wherein a width of the second portion of the first bonding contact in the first direction is substantially the same as a width of the first bonding pad in the first direction.

8. The memory device of claim 4, wherein an upper surface of the first portion of the first bonding contact forms substantially the same plane as an upper surface of the bit line.

9. The memory device of claim 1, wherein the first bonding contact includes a first portion located within the bit line and a second portion located below the bit line,
wherein a surface of the first portion of the first bonding contact contacting the bit line forms substantially the same plane as one side of the second portion of the first bonding contact.

10. The memory device of claim 9, wherein the bit line includes a first portion contacting one side of the first bonding contact and a second portion contacting the other side opposite the one side of the first bonding contact,
wherein the first portion of the bit line does not overlap with the second portion of the first bonding contact.

11. The memory device of claim 10, wherein a lower surface of the second portion of the bit line is in contact with the second portion of the first bonding contact.

12. A memory device comprising:
a first semiconductor structure including a bit line extending in a first direction;
a second semiconductor structure disposed below the first semiconductor structure;
a first bonding structure disposed between the first semiconductor structure and the second semiconductor structure, and including a first bonding insulating layer, a first bonding pad disposed within the first bonding insulating layer, and a first bonding contact connected to the first bonding pad; and
a second bonding structure disposed between the first bonding structure and the second semiconductor structure, and including a second bonding insulating layer, a second bonding pad disposed within the second bonding insulating layer and having an upper surface in contact with a lower surface of the first bonding pad, and a second bonding contact connected to the second bonding pad;
wherein the bit line includes a first portion and a second portion spaced apart from the first portion in the first direction, and the first bonding contact is located between the first portion and the second portion of the bit line.

13. The memory device of claim 12, wherein the first portion of the bit line overlaps with the second portion in the first direction.

14. The memory device of claim 13, wherein the first portion and the second portion of the bit line are electrically connected.

15. The memory device of claim 12, wherein the first portion of the bit line is in contact with one side of the first bonding contact, and the second portion of the bit line is in contact with the other side opposite the one side of the first bonding contact.

16. The memory device of claim 12, wherein the first bonding contact includes a first portion overlapping with the bit line in the first direction and a second portion located below the first portion of the first bonding contact,
wherein a width of the second portion of the first bonding contact in the first direction is greater than a width of the first portion of the first bonding contact in the first direction.

17. The memory device of claim 16, wherein an upper surface of the second portion of the first bonding contact is in contact with the bit line.

18. The memory device of claim 12, wherein the first bonding contact includes a first portion overlapping with the bit line in the first direction and a second portion positioned below the first portion of the first bonding contact,
wherein one side of the first portion of the bit line forms substantially the same plane as one side of the second portion of the first bonding contact.

19. The memory device of claim 18, wherein the first portion of the bit line does not overlap with the second portion of the first bonding contact.

20. A memory device comprising:
a stack of first and second semiconductor structures bonded together via a bonding structure,
wherein the first semiconductor structure includes a bit line extending in a first direction,
wherein the bonding structure includes a first bonding contact which includes a first portion overlapping with the bit line in the first direction and a second portion positioned below the first portion of the first bonding contact, and
wherein the first portion of the first bonding contact separates the bit line in two parts.
